(19) United States
(12) Patent Application Publication
(10) Pub. No.: US 2015/0069450 A1
(43) Pub. Date: Mar. 12, 2015

(54) LIGHT EMITTING MODULE

(71) Applicant: Lextar Electronics Corporation, Hsinchu (TW)

(72) Inventors: Chia-Ming SUNG, Hsinchu County (TW); Yu-Chun LEE, Hsinchu County (TW)

(73) Assignee: Lextar Electronics Corporation, Hsinchu (TW)

(21) Appl. No.: 14/248,319

(22) Filed: Apr. 8, 2014

(30) Foreign Application Priority Data
Sep. 10, 2013 (TW) 102132620

(51) Int. Cl. H01L 33/62; H01L 33/36; H01L 33/52

(52) U.S. Cl. CPC H01L 33/62; H01L 33/52; H01L 33/36
USPC 257/99

(57) ABSTRACT

The present disclosure provides a light emitting module including a substrate, a light emitting diode, a first adhesive glue, and a second adhesive glue. The substrate has a first electrode and a second electrode. The light emitting diode is disposed on the substrate and has a third electrode and a fourth electrode. The first adhesive glue is located between the first electrode and the second electrode so as to enable the first electrode to be electrically connected to the second electrode. The second adhesive glue is located between the third electrode and the fourth electrode, so as to enable the third electrode to be electrically connected to the fourth electrode. The first adhesive glue includes a first conductive body and a first insulation body surrounding the first conductive body. The second adhesive glue includes a second conductive body and a second insulation body surrounding the second conductive body.

### RELATED APPLICATIONS

This application claims priority to Taiwan Application Serial Number 102132620, filed Sep. 10, 2013, which is herein incorporated by reference.

### BACKGROUND

1. Technical Field

The present disclosure relates to a light emitting module,

2. Description of Related Art

In the production a conventional light emitting module, a surface mounting process of surface mounted technology (STM) is performed to bond the light emitting diode on the substrate using solder. However, during the surface mounting process, instability occurs because different production machines have different tolerances, or various components have different temperature performances. As such, solders at different places may be electrically connected with each other to cause a short circuit. Further, in a next curing process after the surface mounting process, the solders at different places are possibly molten again under a high temperature, which also causes the respective solders to be electrically connected with each other. A general solution is to use a metal with higher melting temperature as the solder. However, when the melting point becomes higher, the processing temperature in the surface mounting process must increase with the higher melting temperature of the materials used as the solders. Consequently, more energy is consumed, much less the higher damage risks of the components during the surface mounting process.

### SUMMARY

The present disclosure provides a light emitting module including a substrate, a light emitting diode, a first adhesive glue, and a second adhesive glue. The substrate has a first electrode and a second electrode. The light emitting diode is disposed on the substrate and has a third electrode and a fourth electrode. The first adhesive glue is located between the first electrode and the second electrode so as to enable the first electrode to be electrically connected to the second electrode. The first adhesive glue includes a first conductive body and a first insulation body surrounding the first conductive body. The second adhesive glue is located between the third electrode and the fourth electrode so as to make the third electrode be electrically connected to the fourth electrode. The second adhesive glue includes a second conductive body and a second insulation body surrounding the second conductive body, and thus the first adhesive glue and the second adhesive glue are not electrically connected to each other.

In an embodiment of the present disclosure, the light emitting diode is a light emitting diode package. The light emitting diode package includes a lead frame, a carrier, a light emitting diode chip, and a first encapsulant. The carrier covers a part of the lead frame and exposes a bonding zone of the lead frame, the third electrode, and the fourth electrode. The light emitting diode chip is disposed on the bonding zone and electrically connected to the third electrode and the fourth electrode. The first encapsulant is filled into the bonding zone of the carrier and covers the light emitting diode chip.

In an embodiment of the present disclosure, the light emitting diode is a light emitting diode chip.

In an embodiment of the present disclosure, the light emitting module further includes a second encapsulant covering the light emitting diode chip.

In an embodiment of the present disclosure, the light emitting diode chip is a flip chip.

In an embodiment of the present disclosure, the first conductive body and the second conductive body are tin, copper-tin alloy, gold-tin alloy, or the combination thereof.

In an embodiment of the present disclosure, the first insulation body and the second insulation body include silicone, epoxy, acrylate, acrylic, or the combination thereof.

The present disclosure further provides another light emitting module including a lead frame, a carrier, a light emitting diode chip, a first adhesive glue, and a second adhesive glue. The lead frame includes a predetermined bonding zone. The bonding zone includes a first electrode and a second electrode not electrically connected to each other. The carrier covers a part of the lead frame and exposes the bonding zone of the lead frame, the first electrode, and the second electrode. The light emitting diode chip is disposed on the bonding zone and has a third electrode and a fourth electrode. The first adhesive glue is located between the first electrode and the second electrode so as to enable the first electrode to be electrically connected to the second electrode. The first adhesive glue includes a first conductive body and a first insulation body surrounding the first conductive body. The second adhesive glue is located between the third electrode and the fourth electrode so as to enable the third electrode to be electrically connected to the fourth electrode. The second adhesive glue includes a second conductive body and a second insulation body surrounding the second conductive body, and thus the first adhesive glue and the second adhesive glue are not electrically connected to each other.

In an embodiment of the present disclosure, the light emitting module further includes an encapsulant covering the light emitting diode chip.

In an embodiment of the present disclosure, the light emitting diode chip is a flip chip.

In an embodiment of the present disclosure, the first conductive body and the second conductive body are made of tin, copper-tin alloy, gold-tin alloy, or the combination thereof.

In an embodiment of the present disclosure, the first insulation body and the second insulation body include silicone, epoxy, acrylate, acrylic, or the combination thereof.

Accordingly, the light emitting module of the present disclosure can solve a short circuit problem caused by solders at different places of a conventional light emitting module that are electrically connected to each other during the manufacturing processes. The present disclosure replaces the conventional solder into the composite glue having a conductive body and an insulation body.

The composite glue is electrically conductive and has the function of isolating from another composite glue, so that the short circuit problem during the manufacturing processes can be solved. The present disclosure effectively solves the short circuit problem when the light emitting diode package is electrically connected to the substrate. The present disclosure can also prevent the short circuit problem when the light emitting diode chip is electrically connected to the substrate directly. The present disclosure can also improve the short circuit problem within the light emitting diode package. Thus, the production yield of the light emitting module can be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a light emitting module according to an embodiment of the present disclosure;

FIG. 2 is a cross-sectional view of a light emitting module according to another embodiment of the present disclosure;

FIG. 3 is a cross-sectional view of a light emitting module according to another embodiment of the present disclosure;

FIG. 4 is a cross-sectional view of a composite glue in FIG. 3 along line 4-4′ before curing; and

FIG. 5 is a cross-sectional view of the composite glue in FIG. 3 along line 4-4 after curing.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

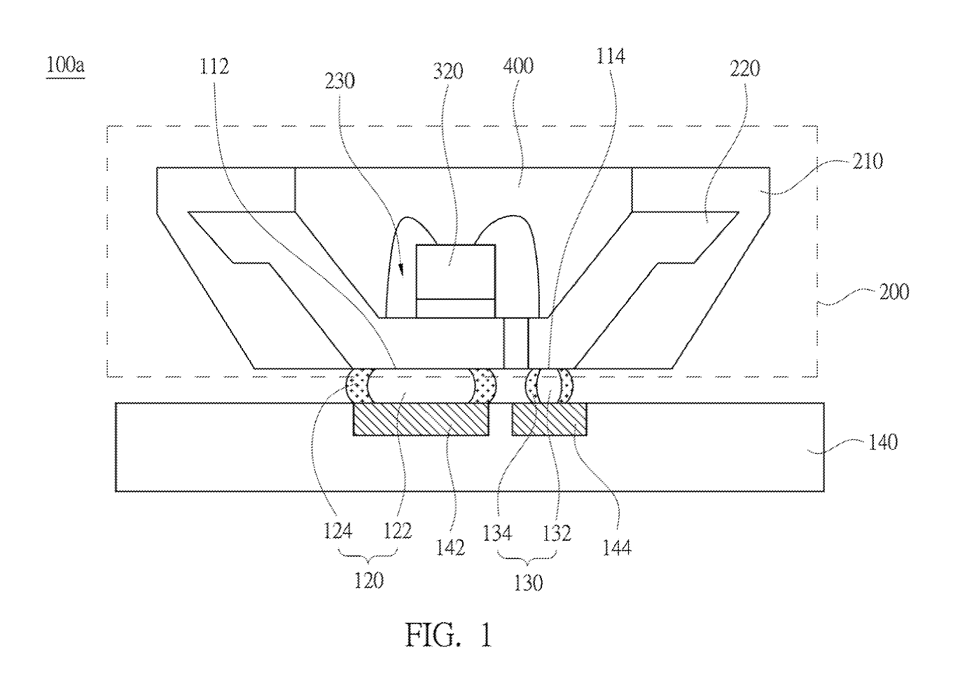

In order to solve a problem that solders of a conventional light emitting module may cause a short circuit, the present disclosure provides a light emitting module to improve the problem. FIG. 1 is a cross-sectional view of a light emitting module according to an embodiment of the present disclosure. The light emitting module 100a has a substrate 140, a light emitting diode 200, a first adhesive glue 120, and a second adhesive glue 130. In this embodiment of the present disclosure, the light emitting diode 200 is a light emitting diode package. The substrate 140 has a first electrode 142 and a second electrode 144. The light emitting diode package (i.e., the light emitting diode 200) is disposed on the substrate 140 and has a third electrode 112, and a fourth electrode 114. The first adhesive glue 120 is located between the first electrode 142 and the second electrode 144 so as to make the first electrode 142 be connected to the second electrode 144. The first adhesive glue 120 includes a first conductive body 122 and a first insulation body 124 surrounding the first conductive body 122. The second adhesive glue 130 is located between the third electrode 112 and the fourth electrode 114, so as to enable the third electrode 112 to be electrically connected to the fourth electrode 114. The second adhesive glue 130 includes a second conductive body 132 and a second insulation body 134 surrounding the second conductive body 132, and thus the first adhesive glue 120 and the second adhesive glue 130 are not electrically connected to each other. The light emitting diode package includes a lead frame 220, a carrier 210, a light emitting diode chip 320, and a first encapsulant 400. The carrier 210 covers a part of the lead frame 220 and exposes a bonding zone 230 of the lead frame 220, the third electrode 112, and the fourth electrode 114. The light emitting diode chip 320 is disposed on the bonding zone 230 and electrically connected to the third electrode 112 and the fourth electrode 114. The first encapsulant 400 is filled into the bonding zone 230 of the carrier 210 and covers the light emitting diode chip 320. The first conductive body 122 and the second conductive body 132 are tin, copper-tin alloy, gold-tin alloy, or the combination thereof. The first insulation body 124 and the second insulation body 134 include silicone, epoxy, acrylate, acrylic, or the combination thereof. The present disclosure uses a composite glue in place of the conventional solders in order to rule out the possibility of electrical connection between the solders during manufacturing processes. Thus, the problem of short circuit is solved.

People having ordinary skill in the art can make proper modification to the materials of the first conductive body 122, the second conductive body 132, the first insulation body 124, and the second insulation body 134 according to their actual needs.

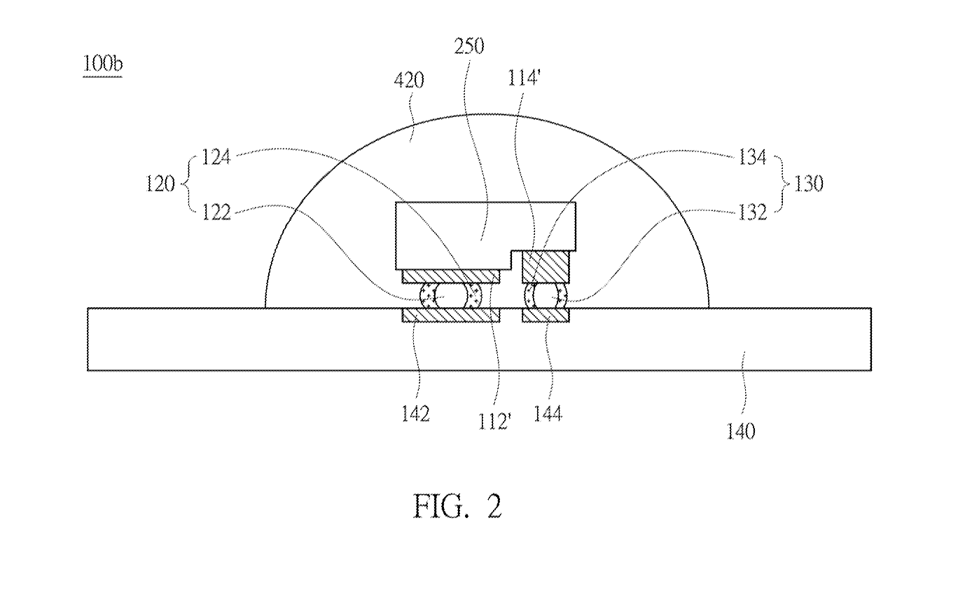

FIG. 2 is a cross-sectional view of a light emitting module according to another embodiment of the present disclosure. The light emitting module 100b has a substrate 140, a light emitting diode 250, a first adhesive glue 120, a second adhesive glue 130, and the second encapsulant 420. In this embodiment of the present disclosure, the light emitting diode 250 is the light emitting diode chip. The second encapsulant 420 covers the light emitting diode chip (i.e., the light emitting diode 250), and the light emitting diode chip is a flip chip. The substrate 140 has a first electrode 142 and a second electrode 144. The light emitting diode chip is disposed on the substrate 140 and has a third electrode 112′, and a fourth electrode 114. The first adhesive glue 120 is located between the first electrode 142 and the second electrode 144 so as to enable the first electrode 142 to be electrically connected to the second electrode 144. The first adhesive glue 120 includes a first conductive body 122 and a first insulation body 124 surrounding the first conductive body 122. The second adhesive glue 130 is located between the third electrode 112′ and the fourth electrode 114′ so as to enable the third electrode 112 to be electrically connected to the fourth electrode 114′. The second adhesive glue 130 includes a second conductive body 132 and a second insulation body 134 surrounding the second conductive body 132, and thus the first adhesive glue 120 and the second adhesive glue 130 are not electrically connected to each other. The present disclosure uses a composite glue in place of the conventional solders in order to rule out the possibility of electrical, connection between the solders during manufacturing processes. Thus, the problem of short circuit is solved. The first conductive body 122 and the second conductive body 132 are tin, copper-tin alloy, gold-tin alloy, or the combination thereof. The first insulation body 124 and the second insulation body 134 include silicone, epoxy, acrylate, acrylic, or the combination thereof.

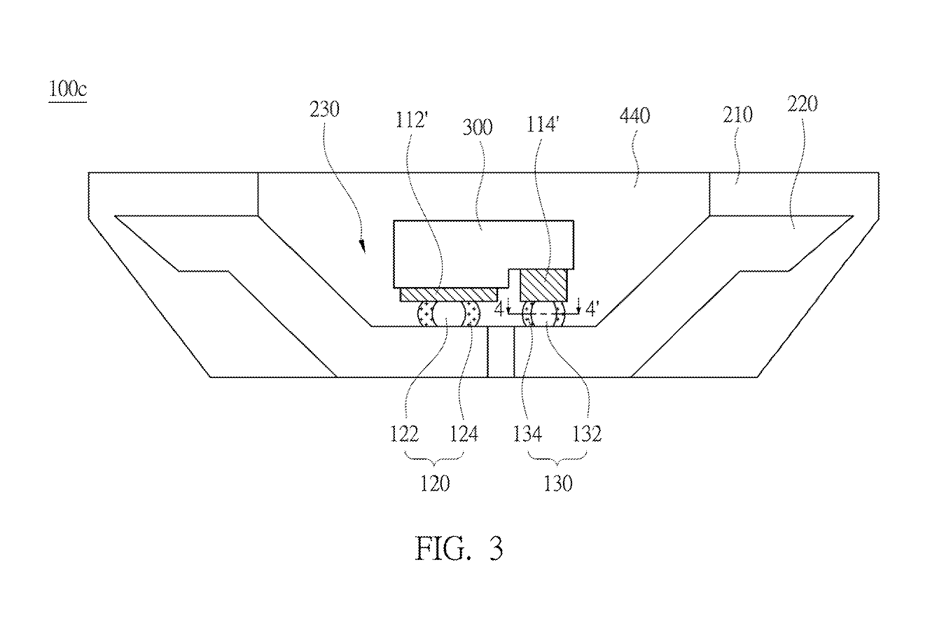

FIG. 3 is a cross-sectional view of a light emitting module according to another embodiment of the present disclosure. The light emitting module 100c has a lead frame 220, a carrier 210, a light emitting diode chip 300, a first adhesive glue 120, a second adhesive glue 130, and a encapsulant 440. The encapsulant 440 covers the light emitting diode chip 300, and the light emitting diode chip 300 is flip chip. The lead frame 220 includes a predetermined bonding zone 230. The bonding zone 230 includes a first electrode 142′ and a second electrode 144′ not electrically connected to each other. The carrier 210 covers a part of the lead frame 220 and exposes the bonding zone 230 of the lead frame 220, the first electrode 142′, and the second electrode 144′. The light emitting diode chip 300 is disposed on the bonding zone 230. The light emitting diode chip 300 has a third electrode 112′, and a fourth electrode 114′. The first adhesive glue 120 is located between the first electrode 142′ and the second electrode 144′ to make the first electrode 142′ electrically connected to the second electrode 144′. The first adhesive glue 120 includes a first conductive body 122 and a first insulation body 124 surrounding the first conductive body 122. The second adhesive glue 130 is located between the third electrode 112′ and the fourth electrode 114′ to make the third electrode 112′ electrically connected to the fourth electrode 114′. The second adhesive glue 130 includes a second conductive body 132 and a second insulation body 134 surrounding the second conductive body 132, and thus the first adhesive glue 120 and the second adhesive glue 130 are not electrically connected to each other. The present disclosure uses a composite glue in place of the conventional solders in order to rule out the possibility of electrical connection between the solders during manufacturing processes. Thus, the problem of short circuit is solved. The first conductive body 122 and the second conductive body 132 are tin, copper-tin alloy, gold-tin alloy, or the combination thereof. The first insulation body 124 and the second insulation body 134 include silicone, epoxy, acrylate, acrylic, or the combination thereof.

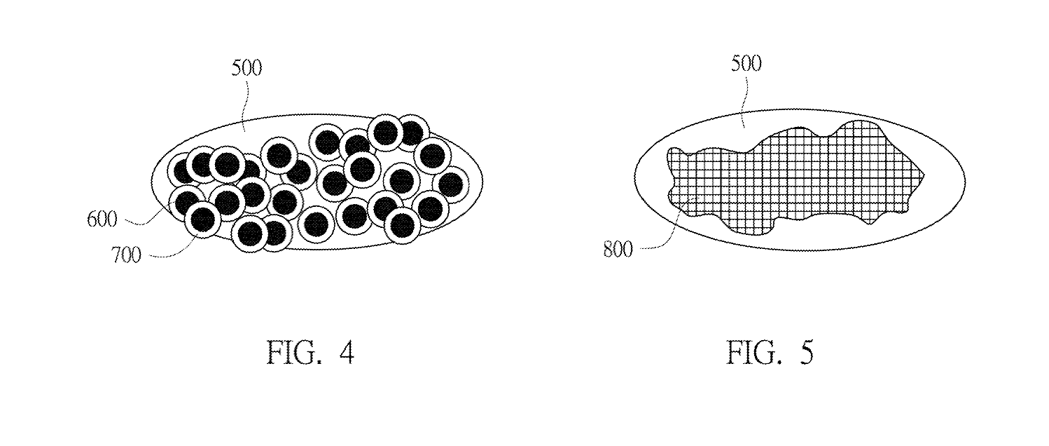

FIG. 4 is a cross-sectional view of a composite glue in FIG. 3 along line 4-4′ before curing. FIG. 5 is a cross-sectional view of the composite glue in FIG. 3 along line 4-4′ after curing. The composite glue is made of a glue 500, a first metal 600, and the second metal 700. The second metal 700 wraps up the first metal 600 and distributes randomly in the glue 500. After the composite glue goes through the curing processes, the first metal 600 and the second metal 700 are heated to form an alloy 800, and the glue 500 wraps up the alloy 800. The alloy 800 becomes a conductive body, and the glue 500 becomes an insulation body. Because the glue 500 and the alloy 800 have different chemical properties, they do not melt together. In an embodiment of the present disclosure, the first metal 600 is tin, the second metal 700 is copper or gold, and thus the alloy 800 is a copper-tin alloy or a gold-tin alloy.

Accordingly, the light emitting module of the present disclosure can solve a short circuit problem caused by solders at different places of a conventional light emitting module that are electrically connected to each other during the manufacturing processes. The present disclosure replaces the conventional solder into the composite glue having a conductive body and an insulation body. The composite glue is electrically conductive and has the function of isolating from another composite glue, so that the short circuit problem during the manufacturing processes can be solved. The present disclosure effectively solves the short circuit problem when the light emitting diode package is electrically connected to the substrate. The present disclosure can also prevent the short circuit problem when the light emitting diode chip is electrically connected to the substrate directly. The present disclosure can also improve the short circuit problem within the light emitting diode package. Thus, the production yield of the light emitting module can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fail within the scope of the following claims.

What is claimed is:

1. A light emitting module, comprising:
a substrate having a first electrode and a second electrode;
a light emitting diode disposed on the substrate and having a third electrode and a fourth electrode;
a first adhesive glue located between the first electrode and the second electrode, enabling the first electrode to be electrically connected to the second electrode, wherein the first adhesive glue comprises a first conductive body and a first insulation body surrounding the first conductive body; and
a second adhesive glue located between the third electrode and the fourth electrode, enabling the third electrode to be electrically connected to the fourth electrode, wherein the second adhesive glue comprises a second conductive body and a second insulation body surrounding the second conductive body, and thus the first adhesive glue and the second adhesive glue are not electrically connected to each other.

2. The light emitting module of claim 1, wherein the light emitting diode is a light emitting diode package, and the light emitting diode package comprises:
a lead frame;
a carrier covering a part of the lead frame and exposing a bonding zone of the lead frame, the third electrode, and the fourth electrode;
a light emitting diode chip disposed on the bonding zone and electrically connected to the third electrode and the fourth electrode; and
a first encapsulant filled into the bonding zone of the carrier and covering the light emitting diode chip.

3. The light emitting module of claim 1, wherein the light emitting diode is a light emitting diode chip.

4. The light emitting module of claim 3, further comprising a second encapsulant covering the light emitting diode chip.

5. The light emitting module of claim 3, wherein the light emitting diode chip is a flip chip.

6. The light emitting module of claim 1, wherein the first conductive body and the second conductive body are tin, copper-tin alloy, gold-tin alloy, or the combination thereof.

7. The light emitting module of claim 1, wherein the first insulation body and the second insulation body comprise silicone, epoxy, acrylate, acrylic, or the combination thereof.

8. A light emitting module, comprising:
a lead frame comprising a predetermined bonding zone, the bonding zone comprising a first electrode and a second electrode not electrically connected to each other;
a carrier covering a part of the lead frame and exposing the bonding zone of the lead frame, the first electrode, and the second electrode;
a light emitting diode chip disposed on the bonding zone and having a third electrode and a fourth electrode;
a first adhesive glue located between the first electrode and the second electrode, enabling the first electrode to be electrically connected to the second electrode, wherein the first adhesive glue comprises a first conductive body and a first insulation body surrounding the first conductive body; and
a second adhesive glue located between the third electrode and the fourth electrode, enabling the third electrode to be electrically connected to the fourth electrode, wherein the second adhesive glue comprises a second conductive body and a second insulation body surrounding the second conductive body, and thus the first adhesive glue and the second adhesive glue are not electrically connected to each other.

9. The light emitting module of claim 8, further comprising an encapsulant covering the light emitting diode chip.

10. The light emitting module of claim 8, wherein the light emitting diode chip is a flip chip.

11. The light emitting module of claim 8, wherein the first conductive body and the second conductive body are made of tin, copper-tin alloy, gold-tin alloy, or the combination thereof.

12. The light emitting module of claim 8, wherein the first insulation body and the second insulation body comprise silicone, epoxy, acrylate, acrylic, or the combination thereof.
